(19) United States
(12) Patent Application Publication
(10) Pub. No.: US 2026/0287898 A1
(43) Pub. Date: Sep. 24, 2026

(54) OPTICAL COUPLING ELEMENT ASSEMBLY, OPTICAL ENGINE, IMAGE DISPLAY DEVICE, XR GLASSES, AND METHOD FOR MANUFACTURING OPTICAL COUPLING ELEMENT ASSEMBLY

(71) Applicant: TDK Corporation, Tokyo (JP)

(72) Inventors: Takashi Honda, Tokyo (JP); Tsuyoshi Komaki, Tokyo (JP); Taku Someya, Tokyo (JP); Yusuke Shigeta, Tokyo (JP); Kenta Yano, Tokyo (JP)

(73) Assignee: TDK Corporation, Tokyo (JP)

(21) Appl. No.: 19/544,481

(22) Filed: Feb. 19, 2026

(30) Foreign Application Priority Data
Mar. 19, 2025 (JP) 2025-044286

(51) Int. Cl. G02B 27/01; G02B 26/10; H01S 5/02326

(52) U.S. Cl. CPC G02B 27/0172; G02B 26/105; H01S 5/02326; G02B 2027/0114; G02B 2027/0178

(57) ABSTRACT

This optical coupling element assembly includes a plurality of laser light sources mounted on a subcarrier, a lens unit in which lenses are arranged side by side, and a prism unit formed by integrally combining a plurality of prisms. The subcarrier and the lens unit are bonded. The lens unit and the prism unit are bonded. Each of the prisms includes an inclined surface which reflects and/or transmits a laser light ray and the prisms are arranged parallel to each other such that the laser light rays reflected and/or transmitted are coupled into a single laser light ray.

### BACKGROUND OF THE INVENTION

### Field of the Invention

The present disclosure relates to an optical coupling element assembly, an optical engine, an image display device, XR glasses, and a method for manufacturing an optical coupling element assembly.

The present application claims priority on Japanese Patent Application No. 2025-044286 filed on March 19, 2025, the content of which is incorporated herein by reference.

### Description of Related Art

Optical element assemblies for XR glasses, such as augmented reality (AR) glasses and virtual reality (VR) glasses incorporating a plurality of laser diodes, are expected to serve as compact wearable devices. In wearable devices such as AR glasses and VR glasses, miniaturization such that all functions fit within an ordinary eyeglass form factor is the key to widespread adoption.

A projector module using a spatial optical system as an optical element coupling and outputting red, green, and blue laser light has been proposed (for example, refer to Patent Document 1). In addition, an integrated optical device using optical waveguides has been proposed (for example, refer to Patent Document 2).

### Patent Document

Patent Document 1 Specification of United States Patent Application, Publication No. 2024/0168305

Patent Document 2 Japanese Patent No. 7514094

### SUMMARY OF THE INVENTION

In the projector module proposed in Patent Document 1, it is necessary to perform positioning of lenses and the like individually, which results in a heavy assembly workload, including a fixing process.

In addition, in the integrated optical device proposed in Patent Document 2, in order to minimize coupling loss between laser diodes and optical waveguides, positioning of the laser diodes is important, and adjustment by active alignment is required.

The present disclosure has been made in consideration of the foregoing circumstances, and an object thereof is to provide an optical coupling element assembly in which a positioned input light source unit and a coupling unit are integrated, an optical engine, an image display device, XR glasses, and a method for manufacturing an optical coupling element assembly.

In order to solve the foregoing problems, the present disclosure provides the following features.

According to Aspect 1 of the present disclosure, there is provided an optical coupling element assembly including a plurality of laser light sources mounted on a subcarrier, a lens unit in which a plurality of lenses are arranged side by side to convert a plurality of laser light rays output from the plurality of laser light sources into mutually parallel collimated rays, and a prism unit formed by integrally combining a plurality of prisms to which a plurality of laser light rays that have passed through the lens unit are respectively input. A bonding surface of the subcarrier and a first bonding surface of the lens unit are bonded to each other. A second bonding surface of the lens unit and a bonding surface of the prism unit are bonded to each other. Each of the plurality of prisms includes an inclined surface reflecting and/or transmitting the laser light ray, the inclined surfaces are arranged parallel to each other such that the plurality of laser light rays reflected and/or transmitted are coupled into a single laser light ray, and the coupled laser light ray is output from an exit of the prism unit.

According to Aspect 2 of the present disclosure, in the optical coupling element assembly according to Aspect 1, the inclined surface of each of the prisms is coated with a thin film having wavelength selectivity, or has a microstructure formed thereon so as to have wavelength selectivity.

According to Aspect 3 of the present disclosure, in the optical coupling element assembly according to Aspect 1 or 2, either one of the first bonding surface of the lens unit or the bonding surface of the subcarrier has an alignment marker for positioning a counterpart to be bonded.

According to Aspect 4 of the present disclosure, in the optical coupling element assembly according to any one of Aspects 1 to 3, either one of the second bonding surface of the lens unit or the bonding surface of the prism unit has an alignment marker for positioning a counterpart to be bonded.

According to Aspect 5 of the present disclosure, in the optical coupling element assembly according to any one of Aspects 1 to 4, bonding between the bonding surface of the subcarrier and the first bonding surface of the lens unit is metal bonding or bonding using a UV-curable resin.

According to Aspect 6 of the present disclosure, in the optical coupling element assembly according to any one of Aspects 1 to 5, bonding between the second bonding surface of the lens unit and the bonding surface of the prism unit is metal bonding or bonding using a UV-curable resin.

According to Aspect 7 of the present disclosure, in the optical coupling element assembly according to any one of Aspects 1 to 6, each of the plurality of laser light sources is installed on the subcarrier at a position spaced apart from the first bonding surface of the lens unit by a distance of 0 μm to 50 μm.

According to Aspect 8 of the present disclosure, in the optical coupling element assembly according to any one of Aspects 1 to 7, the subcarrier is made of aluminum nitride, aluminum oxide, or silicon.

According to Aspect 9 of the present disclosure, in the optical coupling element assembly according to any one of Aspects 1 to 8, the lens unit includes a lens base having a plurality of recesses, and the lenses are respectively accommodated and fixed in the plurality of recesses.

According to Aspect 10 of the present disclosure, in the optical coupling element assembly according to any one of Aspects 1 to 9, the bonding surface of the subcarrier and the first bonding surface of the lens unit are positioned and bonded such that optical axes of the respective laser light rays output from the laser light sources coincide with optical axes of the respective lenses provided in the lens unit.

According to Aspect 11 of the present disclosure, the optical coupling element assembly according to any one of Aspects 1 to 10 further includes an output optical system member provided downstream of the prism unit. The output optical system member includes a pinhole member having a pinhole for removing noise from the coupled laser light ray, or the output optical system member includes a collimating lens for collimating the coupled laser light ray.

According to Aspect 12 of the present disclosure, in the optical coupling element assembly according to any one of Aspects 1 to 11, the subcarrier is a common member on which all of the plurality of laser light sources are mounted.

According to Aspect 13 of the present disclosure, in the optical coupling element assembly according to any one of Aspects 1 to 12, the plurality of laser light sources are all visible-light laser light sources outputting visible light rays.

According to Aspect 14 of the present disclosure, in the optical coupling element assembly according to any one of Aspects 1 to 13, a plurality of the visible light rays are red light, green light, and blue light.

According to Aspect 15 of the present disclosure, there is provided an optical engine including the optical coupling element assembly according to Aspect 14, and an optical scanning mirror reflecting, while changing an angle thereof, light output from the optical coupling element assembly so as to display an image.

According to Aspect 16 of the present disclosure, there is provided an image display device including the optical engine according to Aspect 15 mounted thereon.

According to Aspect 17 of the present disclosure, there is provided XR glasses including the optical engine according to Aspect 15 mounted thereon.

According to Aspect 18 of the present disclosure, there is provided a method for manufacturing the optical coupling element assembly according to any one of Aspects 1 to 14. The method includes a step of bonding the subcarrier and the plurality of laser light sources, a step of bonding the subcarrier and the lens unit, and a step of bonding the lens unit and the prism unit.

According to Aspect 19 of the present disclosure, in the method for manufacturing the optical coupling element assembly according to Aspect 18, either one of the first bonding surface of the lens unit or the bonding surface of the subcarrier has an alignment marker for positioning a counterpart to be bonded. The subcarrier and the lens unit are positioned and bonded on the basis of positional information of the alignment marker.

According to Aspect 20 of the present disclosure, in the method for manufacturing the optical coupling element assembly according to Aspect 18 or 19, either one of the second bonding surface of the lens unit or the bonding surface of the prism unit has an alignment marker for positioning a counterpart to be bonded. The lens unit and the prism unit are positioned and bonded on the basis of positional information of the alignment marker.

According to the optical coupling element assembly of the present disclosure, it is possible to provide an optical coupling element assembly in which a positioned input light source unit and a coupling unit are integrated.

### BRIEF DESCRIPTION OF THE DRAWINGS

FIG. 1 is a schematic cross-sectional view showing an example of an optical coupling element assembly according to the present disclosure.

FIG. 2 is a schematic cross-sectional view of the optical coupling element assembly shown in FIG. 1, in which members are arranged apart for the sake of explanation.

FIG. 3 is a schematic cross-sectional view showing another example of an optical coupling element assembly according to the present disclosure.

FIG. 4A is a schematic view showing a bonding portion between a subcarrier including a laser light source mounted thereon and a lens unit.

FIG. 4B is a schematic view showing a configuration in which an alignment marker for positioning is provided on a first bonding surface of the lens unit.

FIG. 5 is a schematic view showing a configuration in which alignment markers for positioning are provided on first bonding surfaces of respective lenses.

FIG. 6 is an enlarged schematic cross-sectional view of the bonding portion between the subcarrier and the lens unit.

FIG. 7A is a schematic perspective view of the subcarriers before the subcarriers and the lens unit are bonded.

FIG. 7B is a schematic perspective view of the lens unit before the subcarriers and the lens unit are bonded.

FIG. 8A is a schematic view of a step of bonding the subcarriers and the lens unit, showing before and after bonding.

FIG. 8B is a schematic view of a step of bonding the subcarriers and the lens unit, showing before and after bonding.

FIG. 9A is a schematic plan view of a prism unit.

FIG. 9B is a schematic perspective view when a prism is a right-angle prism mirror.

FIG. 10 is a schematic plan view of an optical coupling element assembly of the present disclosure including an output optical unit.

FIG. 11 is a schematic plan view of a laser module accommodating the optical coupling element assembly of the present disclosure.

FIG. 12 is a view showing a cross section of the optical coupling element assembly arranged inside the laser module shown in FIG. 11, partially cut along an X-Z plane.

FIG. 13 is an explanatory conceptual view of XR glasses according to the present embodiment.

FIG. 14 is a conceptual view showing a state where an image is directly projected onto a retina by laser light output from the laser module according to the embodiment.

### DETAILED DESCRIPTION OF THE INVENTION

Hereinafter, an embodiment will be described in detail with reference to the drawings as appropriate. In the drawings used in the following description, in order to facilitate understanding of the characteristics, characteristic parts may be shown in an enlarged manner for convenience, and dimensional ratios or the like of each constituent element may differ from actual values. Materials, dimensions, and the like exemplified in the following description are merely examples. The present disclosure is not limited thereto and can be suitably modified and carried out within a range in which the effects of the present disclosure are exhibited.

### Optical coupling element assembly

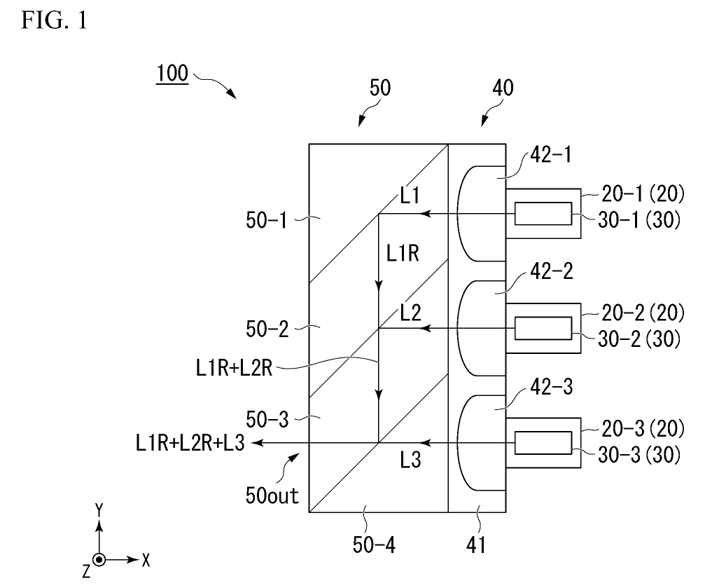

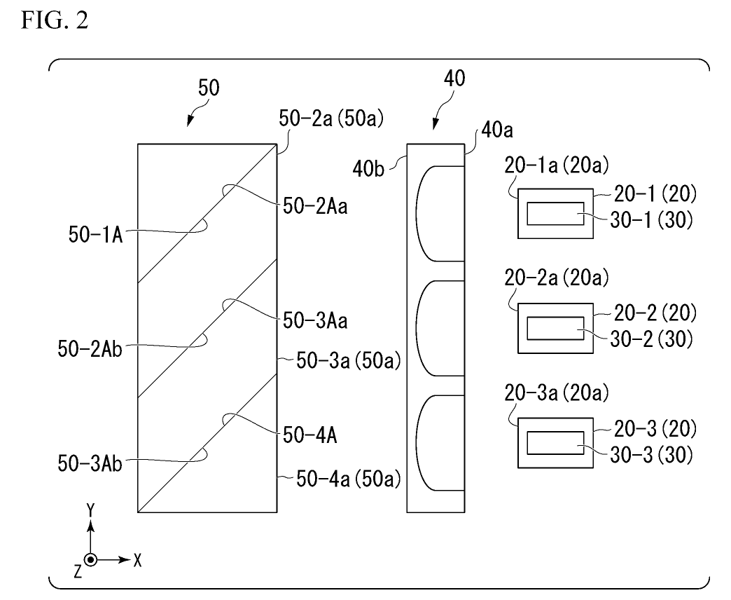

FIG. 1 is a schematic cross-sectional view showing an example of an optical coupling element assembly according to the present disclosure. FIG. 2 is a schematic cross-sectional view of the optical coupling element assembly shown in FIG. 1, in which members are arranged apart for the sake of explanation.

Here, in FIGS. 1 and 2, an X direction is a direction in which subcarriers and a lens unit are coupled and arranged. A Y direction is a direction orthogonal to the X direction. A Z direction is a direction orthogonal to the X direction and the Y direction and is a direction in which the subcarriers and laser light sources are arranged. FIGS. 1 and 2 are schematic plane views as viewed in a direction parallel to the Z direction.

An optical coupling element assembly 100 shown in FIG. 1 includes three laser light sources 30 (30-1, 30-2, 30-3) respectively mounted on subcarriers 20 (20-1, 20-2, 20-3), a lens unit 40 in which three condensing lenses 42-1, 42-2, and 42-3 are arranged side by side to convert laser light rays L1, L2, and L3 output from the three laser light sources 30 (30-1, 30-2, 30-3) into mutually parallel collimated rays, and a prism unit 50 formed by integrally combining four prisms 50-1, 50-2, 50-3, and 50-4 to which the laser light rays L1, L2, and L3 that have passed through the lens unit 40 are respectively input. Bonding surfaces 20a (20-1a, 20-2a, 20-3a) of the subcarriers 20 (20-1, 20-2, 20-3) and a first bonding surface 40a of the lens unit 40 are bonded to each other. A second bonding surface 40b of the lens unit 40 and a bonding surface of the prism unit 50 are bonded to each other. The prisms 50-1, 50-2, 50-3, and 50-4 include inclined surfaces 50-1A, 50-2Aa, 50-2Ab, 50-3Aa, 50-3Ab, and 50-4A reflecting and/or transmitting the laser light rays. The inclined surfaces 50-1A, 50-2Aa, 50-2Ab, 50-3Aa, 50-3Ab, and 50-4A are arranged parallel to each other such that the laser light rays L1, L2, and L3 reflected and/or transmitted are coupled into a single laser light ray. The coupled laser light ray is output from an exit 50out of the prism unit 50.

### Laser light source

In the optical coupling element assembly 100 shown in FIG. 1, an example including three laser light sources is shown. However, the number is not limited to three, and the assembly need only include a plurality of laser light sources.

In addition, various laser elements can be used as the laser light sources. For example, commercially available laser diodes emitting visible light such as red light, green light, and blue light can be used. Light having a peak wavelength of 630 nm to 830 nm can be used as the red light (R), light having a peak wavelength of 500 nm to 550 nm can be used as the green light (G), and light having a peak wavelength of 380 nm to 500 nm can be used as the blue light (B). In addition, laser diodes emitting near-infrared light, ultraviolet light, and the like can also be used.

Known laser diodes, such as Fabry-Perot type, VCSEL, or PCSEL, can be used.

### Subcarrier

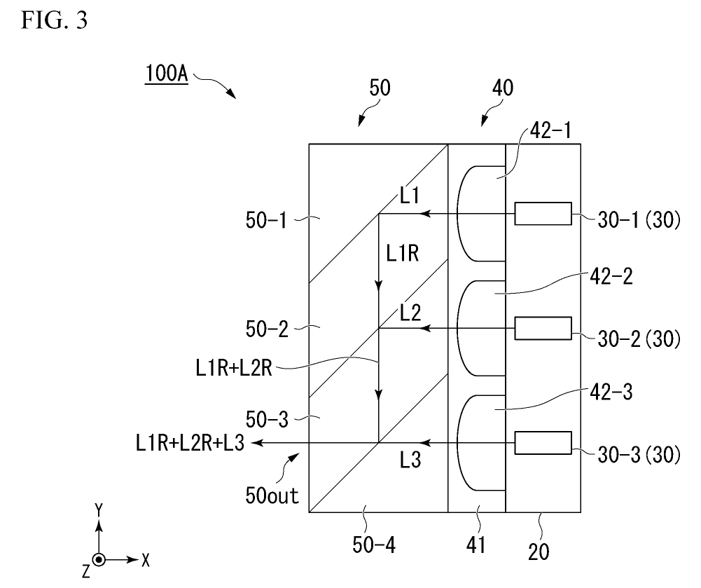

As shown in FIGS. 1 and 2, the subcarriers may be members separately provided for a plurality of respective laser light sources, or may be members shared by a plurality of laser light sources (refer to FIG. 3) as shown in FIG. 3, which will be described below.

In the subcarriers 20 shown in FIG. 1, three laser light sources are separately provided on the respective subcarriers 20-1, 20-2, and 20-3.

Examples of materials of the subcarrier 20 include aluminum nitride (AlN), aluminum oxide (Al₂O₃), and silicon (Si).

For example, the laser light sources 30 may be mounted on the subcarriers 20 in a bare-chip (unpackaged chip) state.

The laser light sources 30 may be mounted on the subcarriers 20 with a metal layer therebetween. As for a method for forming the metal layer, a known method can be utilized without any particular limitations, and a known technique such as sputtering, vapor deposition, or application of a metal paste can be utilized. For example, the metal layer may contain one or a plurality of metals selected from the group consisting of gold (Au), platinum (Pt), silver (Ag), lead (Pb), indium (In), nickel (Ni), titanium (Ti), tantalum (Ta), tungsten (W), an alloy of gold (Au) and tin (Sn), a tin (Sn)-silver (Ag)-copper (Cu)-based solder alloy (SAC), SnCu, InBi, SnPdAg, SnBiIn, and PbBiIn, or may consist of one or a plurality of kinds of metals selected from this group.

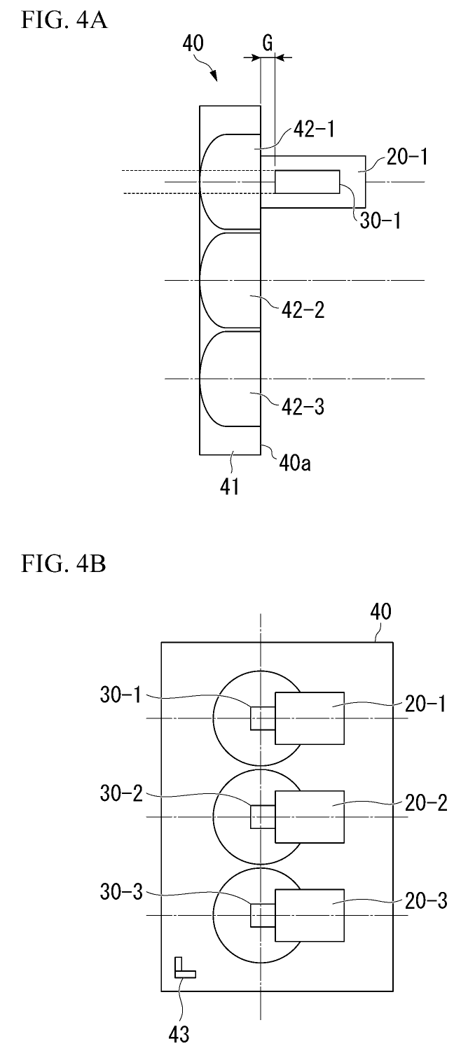

Mounting positions of the laser light sources 30-1, 30-2, and 30-3 on respective upper surfaces of the subcarriers 20-1, 20-2, and 20-3 are set such that a distance G (air gap, refer to FIG. 4A) between output surfaces of the laser light and a bonding surface 40a of the lens unit 40 coincides with focal lengths of the condensing lenses 42-1, 42-2, and 42-3. That is, the respective condensing lenses 42-1, 42-2, and 42-3 are laid out such that focal points thereof coincide with light emission points (light emitting positions) of laser light from the respective laser light sources 30-1, 30-2, and 30-3.

An optical coupling element assembly 100A shown in FIG. 3 is configured to include the three laser light sources 30 (30-1, 30-2, 30-3) mounted on the subcarriers 20, the lens unit 40 in which the three condensing lenses 42-1, 42-2, and 42-3 are arranged side by side to condense the laser light rays L1, L2, and L3 output from the three laser light sources 30 (30-1, 30-2, 30-3), and the prism unit 50 formed by integrally combining the four prisms 50-1, 50-2, 50-3, and 50-4 to which the laser light rays L1, L2, and L3 that have passed through the lens unit 40 are respectively input.

### Lens unit

A lens unit made of a material known as a lens material can be used. Specifically, a lens unit made of a glass material, a plastic material, or the like can be used. Examples of the glass material include BK7 and synthetic quartz, which are representative optical glass materials.

The lens unit 40 shown in FIG. 1 has a configuration in which the three condensing lenses 42-1, 42-2, and 42-3 respectively condensing laser light output from the three laser light sources 30 (30-1, 30-2, 30-3) are arranged side by side in a row. The condensing lenses 42-1, 42-2, and 42-3 are arranged such that directions of their respective optical axes are parallel to each other.

The condensing lenses 42-1, 42-2, and 42-3 may be metalenses or Fresnel lenses.

The lens unit 40 shown in FIG. 1 has a configuration in which the condensing lenses 42-1, 42-2, and 42-3 are accommodated and fixed in respective recesses of a lens base 41 having three recesses. However, a configuration in which the condensing lenses and the lens base are integrally molded may also be adopted.

The bonding surfaces 20a (20-1a, 20-2a, 20-3a) of the subcarriers 20 (20-1, 20-2, 20-3) and the first bonding surface 40a of the lens unit 40 are positioned and bonded such that the optical axes of the laser light rays L1, L2, and L3 output from the three respective laser light sources 30 (30-1, 30-2, 30-3) mounted on the subcarriers 20 coincide with the optical axes of the respective condensing lenses 42-1, 42-2, and 42-3 provided in the lens unit 40.

Here, “coincide with the optical axes” means coincidence to an extent that allows the optical coupling element assembly of the present disclosure to be used without difficulty.

Positioning between the subcarriers 20 having the laser light sources mounted thereon and the lens unit 40 can be performed, for example, by providing an alignment marker at a predetermined position on either one of the bonding surface 20a of the subcarrier 20 or the first bonding surface 40a of the lens unit 40. Based on positional information of the alignment marker, it is possible to identify the positions of the subcarriers 20 and the lens unit 40 in a state where the optical axes of laser light output from the laser light sources coincide with the optical axes (centers of input ports) of the lenses provided in the lens unit 40.

By bonding and combining the subcarriers 20 having the laser light sources mounted thereon with the lens unit 40 in a state where positioning has been performed, required parallel collimated rays can be obtained from diffused light from the laser light sources.

By providing an alignment marker, assembly becomes possible with accuracy at a level allowing positioning of the laser light sources by passive alignment.

The alignment marker is not particularly limited as long as it functions as a positioning mark.

Positioning (positional alignment) using an alignment marker may be performed manually or automatically, or known methods such as utilization of a camera can be used.

The example shown in FIGS. 4A and 4B is configured to have an alignment marker 43 for positioning on the first bonding surface 40a of the lens unit 40.

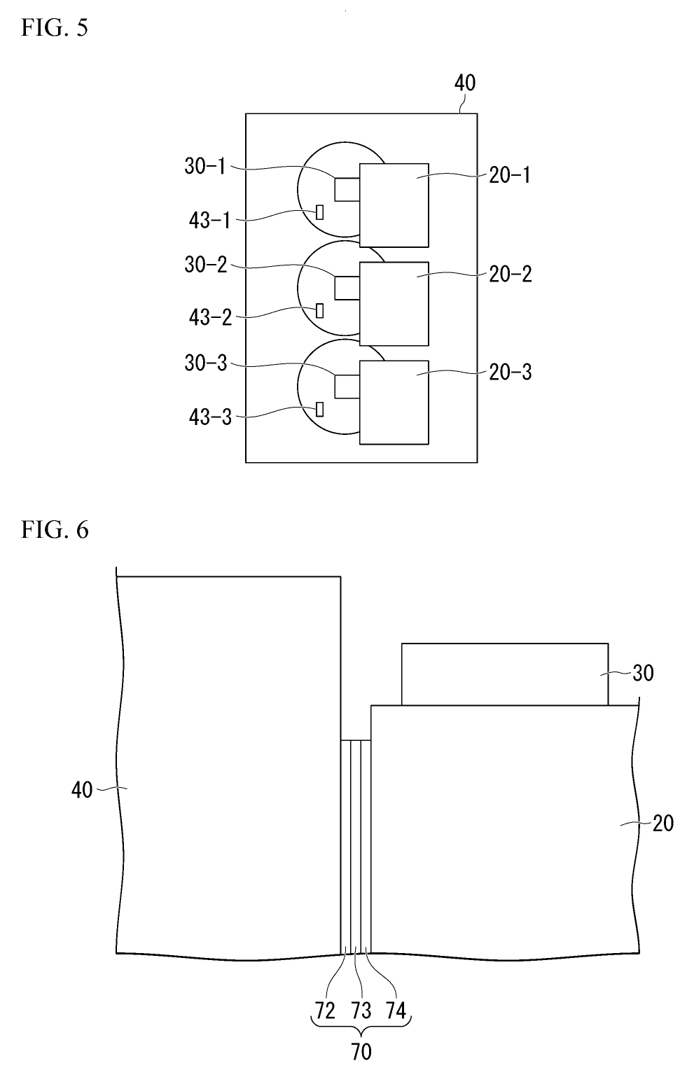

The example shown in FIG. 5 is configured to have alignment markers 43-1, 43-2, and 43-3 for positioning formed on the bonding surfaces of the respective condensing lenses 42-1, 42-2, and 42-3.

Bonding between the subcarriers 20 and the lens unit 40 can be performed by bonding (adhesion) using a UV resin (UV-curable resin) or the like, or by metal bonding such as eutectic bonding.

For example, a known optical adhesive can be used as the UV-curable resin.

Examples of the optical adhesive include refractive-index-adjusted products GA700H, GA700L, AT6001, and AT8224, which are optical adhesives (optical path coupling adhesive) used for PLC fiber bonding (manufactured by NTT Advanced Technology Corporation (NTT-AT)).

The refractive-index-adjusted products are epoxy resins having a refractive index n=1.458 to 1.567, in which
GA700H is an epoxy resin having a refractive index n=1.458,
GA700L is an epoxy resin having a refractive index n=1.456,
AT6001 is an acrylate resin having a refractive index n=1.505, and
AT8224 is an acrylate resin having a refractive index n=1.505.

In addition, examples thereof include optical UV-curable resin Luxidia (manufactured by DIC Corporation) and optical adhesive Optodyne (manufactured by Daikin Industries, Ltd.).

The UV-curable resin can also be used for filling gaps to adjust the refractive index.

When the subcarriers 20 and the lens unit 40 are integrally coupled (metal-bonded) with a metal layer (reference sign 70 in FIG. 6) therebetween, optical axes can be arranged more accurately, and miniaturization can be realized.

As shown in FIG. 6, the metal layer may be a metal laminated film composed of a plurality of metal films. For example, the metal layer 70 can be a metal laminated film composed of three metal films (a first metal layer, a third metal layer, and a second metal layer).

A preferable example of eutectic bonding include Au-Sn bonding. As for a combination of materials for the metal films, a combination of forming Au-Sn bonding during bonding is preferable.

### Bonding portion

A bonding step will be described, by way of example, with reference to a case where bonding between the subcarriers 20 and the lens unit 40 is metal bonding.

FIG. 6 is an enlarged schematic cross-sectional view of the bonding portion between the subcarriers 20 and the lens unit 40.

The subcarriers 20 including the laser light sources 30 mounted thereon and the lens unit 40 are bonded with the metal film 70 therebetween.

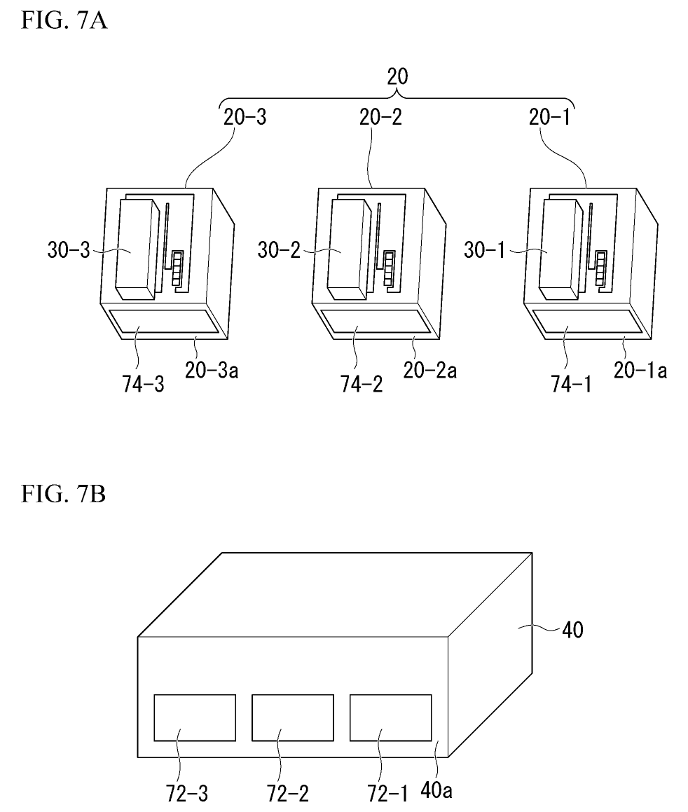

FIG. 7A is a schematic perspective view of three subcarriers respectively including three laser light sources mounted thereon, and FIG. 7B is a schematic perspective view of the lens unit to be bonded to the subcarriers. In FIG. 7B, illustration of the condensing lenses is omitted.

This is a case where the bonding surfaces 20a (20-1a, 20-2a, 20-3a) of the subcarriers 20 (20-1, 20-2, 20-3) and the first bonding surface 40a of the lens unit 40 are bonded with a metal film therebetween.

Metal films 74-1, 74-2, and 74-3 are respectively formed on bonding surfaces 20-1a, 20-2a, and 20-3a of the respective subcarriers 20-1, 20-2, and 20-3.

Meanwhile, the first bonding surface 40a of the lens unit 40 is also provided with metal films 72-1, 72-2, and 72-3 at positions respectively corresponding to the metal films 74-1, 74-2, and 74-3.

Here, in the lens unit 40 shown in FIG. 7B, the metal films 72-1, 72-2, and 72-3 are arranged apart from each other.

When generating moving images or the like using an image display device including the optical coupling element assembly of the present disclosure, an electrical signal applied to a laser light source (for example, a laser diode) is an AC signal.

In this manner, when the operation signal is an AC signal, if a metal film bonding the subcarriers 20 and the lens unit 40 includes a continuously formed band-shaped metal layer as miniaturization progresses, there is concern that capacitive coupling may occur and electrical crosstalk may occur. In the lens unit 40 shown in FIG. 7B, by employing the separated metal films 72-1, 72-2, and 72-3, occurrence of capacitive coupling is curbed, and prevention of crosstalk can be expected.

For convenience, the metal film shown in FIG. 6 is depicted as having a three-layer structure reflecting a process of producing the metal films 70 (which may alternatively be referred to as a process of bonding between the subcarriers and the lens unit). In addition, in description of the metal films 70, each of the three layers may be described.

That is, the metal films 70 shown in the drawing is depicted, for convenience, as being composed of three layers including the first metal films 74 (74-1, 74-2, 74-3) arranged on the respective bonding surfaces 20-1a, 20-2a, and 20-3a of the individual subcarriers 20-1, 20-2, and 20-3, the second metal films 72-1, 72-2, and 72-3 arranged on the first bonding surface 40a of the lens unit 40 corresponding to the respective first metal films 74-1, 74-2, and 74-3, and eutectic layers 73 arranged between the first metal films 74 and the second metal films 72.

In actual bonding, when the first metal films and the second metal films are sufficiently thin, alloy layers (eutectic layers) are formed, and the first metal films and the second metal films do not remain. Meanwhile, when either one of the first metal films or the second metal films is thick, only the surface sides of the thick metal films may become eutectic, leaving parts on the subcarrier side or the lens unit side, while other parts of the metal films may entirely become eutectic. However, it becomes difficult to clearly distinguish them as layers (distinguishing the interface).

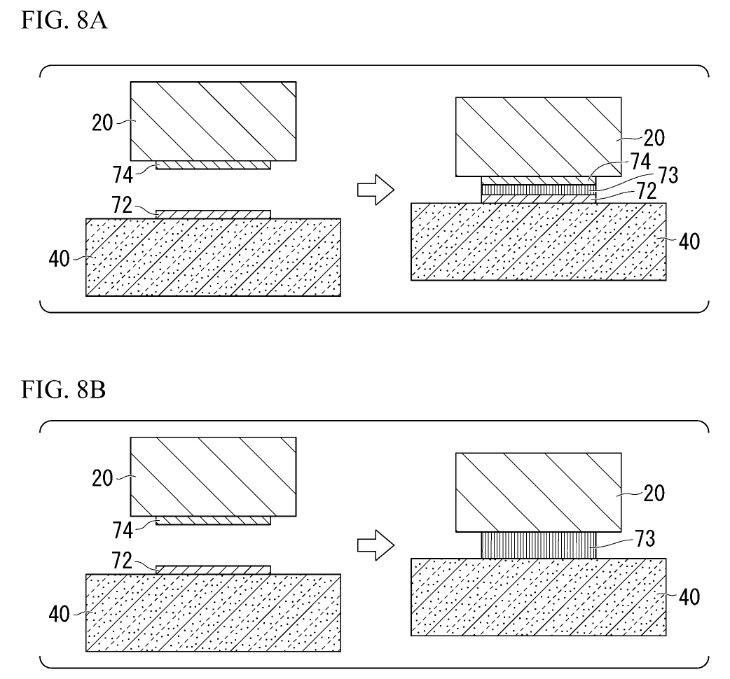

In this manner, in actual bonding, the film structures of the metal films 70 vary depending on conditions of the process of producing the metal films 70. In addition, the drawings conceptually depict characteristic aspects of the film structures. For example, a structure may be adopted in which one or both of the first metal films 74 and the second metal films 72 remain relatively, or a structure may be adopted in which the first metal films 74 and the second metal films 72 are alloyed in their entirety to form eutectic layers. FIG. 8A is a view schematically showing a structure, of the former cases, in which both the first metal films 74 and the second metal films 72 remain relatively, and FIG. 8B is a view schematically showing a structure in which the entirety of the first metal films 74 and the second metal films 72 is alloyed to become an eutectic layer.

### Prism unit

The prism unit is configured to be formed by integrally combining a plurality of prisms. Each of the plurality of prisms includes an inclined surface reflecting and/or transmitting laser light ray, and the inclined surfaces are arranged parallel to each other such that a plurality of laser light rays reflected and/or transmitted are coupled into a single laser light ray, and the coupled laser light is output from the exit of the prism unit.

The distance between the prism unit and the laser light sources is determined by mechanical dimensions of the lens unit.

The inclined surface of the prism is coated with a thin film having wavelength selectivity, or has a microstructure formed thereon so as to have wavelength selectivity.

A prism unit made of a material known as a prism material can be used. Specifically, a prism unit made of a glass material, a plastic material, or the like can be used. Examples of the glass material include BK7 and synthetic quartz, which are representative optical glass materials.

Since the optical coupling element assembly of the present disclosure has a function in which the prism unit changes propagation directions of a plurality of laser light rays and couples them, a plurality of laser light rays can be coupled and output even without providing a precise and dimensionally small optical waveguide structure.

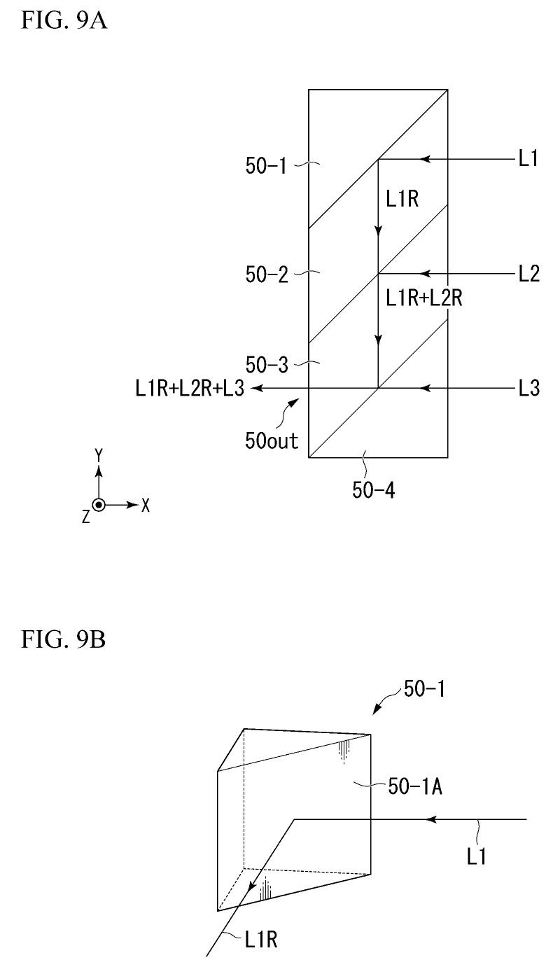

The prism unit 50 shown in FIG. 9A is formed by integrally combining the four prisms 50-1, 50-2, 50-3, and 50-4. The number of prisms is not limited to four.

The prism 50-1 reflects, on an inclined surface 50-1A, the laser light ray L1 input through the condensing lens 42-1, that is, laser light ray output from the laser light source 30-1.

For example, as shown in the schematic perspective view of FIG. 9B, the prism 50-1 is a right-angle prism mirror, and the inclined surface 50-1A is coated with a metal film, a dielectric multilayer film, or the like, thereby reflecting the laser light ray L1 input on the inclined surface 50-1A in a direction perpendicular to the input direction. This reflection is preferably as close to total reflection as possible. When the metal film is a silver (Ag) film, it is possible to achieve an average reflectance of 90% or more over the entire visible light region.

A configuration may be adopted in which fine structures are formed on the inclined surface to selectively reflect and/or transmit light having a particular wavelength.

The prism 50-2 is a hexahedral prism including the inclined surface 50-2Aa bonded to the inclined surface 50-1A of the prism 50-1, and the inclined surface 50-2Ab facing the inclined surface 50-2Aa and parallel to the inclined surface 50-2Aa.

The prism 50-3 is a hexahedral prism including the inclined surface 50-3Aa bonded to the inclined surface 50-2Ab of the prism 50-2, and the inclined surface 50-3Ab facing the inclined surface 50-3Aa and parallel to the inclined surface 50-3Aa.

The prism 50-4 is a triangular prism including the inclined surface 50-4A bonded to the inclined surface 50-3Ab of the prism 50-3. The prism 50-4 may be a right-angle prism mirror.

The laser light ray L1 emitted from the laser light source 30-1 passes through the condensing lens 42-1, enters the prism unit 50, and is reflected by the inclined surface 50-1A of the prism 50-1. Reflected laser light ray L1R travels straight ahead inside the prism 50-2, is transmitted through the inclined surface 50-3Aa (in the case of partial reflection, the reflectance is preferably small), enters the prism 50-3, travels straight ahead inside the prism 50-3, is reflected by the inclined surface 50-4A of the prism 50-4 (in the case of partial transmission, the transmittance is preferably small), and is output from the exit 50out of the prism unit 50.

The laser light ray L2 emitted from the laser light source 30-2 passes through the condensing lens 42-2, enters the prism unit 50, and is reflected by the inclined surface 50-2Ab of the prism 50-2. Reflected laser light ray L2R travels straight ahead inside the prism 50-3. The prism unit 50 is designed such that the inclined surface 50-1A and the inclined surface 50-2Ab are parallel and reflection positions on respective surfaces overlap in the traveling direction of the coupled light (L1R+L2R), so that this laser light ray L2R is coupled to the laser light ray L1R and travels inside the prism 50-3. The coupled light ray (L1R+L2R) is reflected by the inclined surface 50-4A of the prism 50-4 (in the case of partial transmission, the transmittance is preferably small) and is output from the exit 50out of the prism unit 50.

The laser light ray L3 emitted from the laser light source 30-3 passes through the condensing lens 42-3, enters the prism unit 50, is transmitted through the inclined surface 50-3Ab of the prism 50-3 (in the case of partial reflection, the reflectance is preferably small), is coupled to the coupled light ray (L1R+L2R), and is output from the exit 50out of the prism unit 50 as the coupled light ray (L1R+L2R+L3).

Bonding between the second bonding surface 40b of the lens unit 40 and a bonding surface 50a of the prism unit 50 can also be performed by adhesion using a UV-curable resin or the like, or by metal bonding such as AuSn eutectic bonding.

When metal bonding is used, bonding can be performed using a process similar to the metal bonding between the subcarriers 20 and the lens unit 40 described above.

In the optical coupling element assembly of the present embodiment, the subcarrier including the laser light source mounted thereon, the lens unit, and the prism unit are bonded and integrated in a state of being positionally aligned.

### Output optical system

The optical coupling element assembly of the present disclosure may further include an output optical system member provided downstream of the prism unit. The output optical system member may include a pinhole member having a pinhole for removing noise from coupled laser light, a collimating lens for collimating coupled laser light ray, a converging lens for converging coupled laser light ray, or the like.

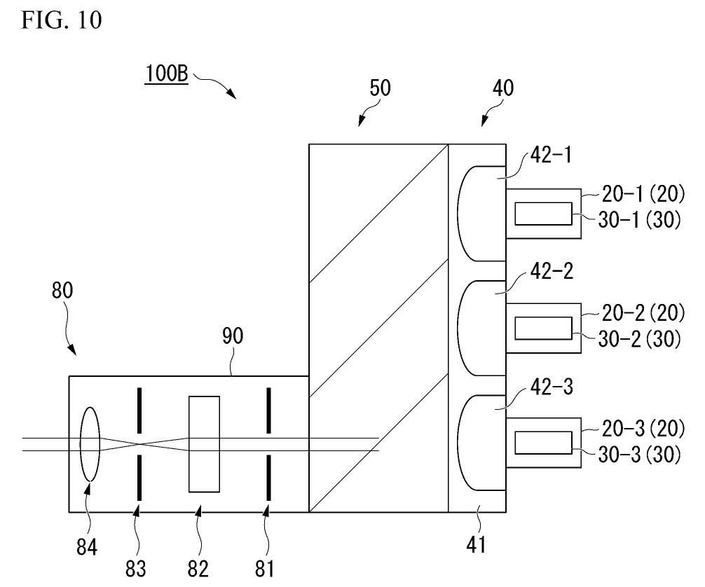

In an output optical unit 80 of an optical coupling element assembly 100B shown in FIG. 10, the reference sign 81 indicates a pinhole member having a pinhole for removing noise light generated around the coupled light ray (L1R+L2R+L3) output from the exit 50out.

In the case of positioning (positional alignment) using an alignment marker, alignment with required accuracy (approximately ±1 μm (‒1 μm to +1 μm)) is possible. However, stray-light processing can be performed in an output-side optical system using the pinhole member 81 to compensate for slight positional deviations.

In the output optical unit 80 shown in FIG. 10, the reference sign 82 indicates a lens (for example, a collimation lens) for shaping an output collimated beam (light ray) into a required beam (light ray). The reference sign 83 indicates a pinhole member for removing noise, and the reference sign 84 indicates a collimation lens for converting an output collimated beam that has passed through the pinhole member 83 into a parallel beam (light ray).

The output optical unit 80 shown in FIG. 10 is fixed to an output optical system base mount 90 in a state where optical components including the pinhole member 81, the shaping lens 82, the pinhole member 83, and the collimation lens 84 are optically and positionally aligned.

A base mount made of the same material as that of as the subcarriers 20 can be used as the output optical system base mount 90, and examples thereof include aluminum nitride (AlN), aluminum oxide (Al₂O₃), and silicon (Si).

The output optical system base mount 90 and the prism unit 50 can be bonded by adhesion using a UV-curable resin or the like, or by metal bonding such as AuSn eutectic bonding.

When metal bonding is used, bonding can be performed using a process similar to the metal bonding between the subcarriers 20 and the lens unit 40 described above.

In the optical coupling element assembly of the present embodiment, the subcarriers including the laser light sources mounted thereon, the lens unit, the prism unit, and the output optical system base mount including the output optical unit mounted thereon are bonded and integrated in a state of being optically and positionally aligned.

### Method for manufacturing optical coupling element assembly

The method for manufacturing an optical coupling element assembly of the present disclosure includes at least a step of bonding a subcarrier and a plurality of laser light sources, a step of bonding the subcarrier and a lens unit, and a step of bonding the lens unit and a prism unit.

In the optical coupling element assembly of the present disclosure, the subcarrier, the lens unit, and the prism unit are positioned, bonded, and integrated. The order in which the subcarrier, the lens unit, and the prism unit are bonded is arbitrary.

For positioning and bonding, an alignment marker may be provided on a bonding surface of any of the subcarrier, the lens unit, and the prism unit, and bonding may be performed on the basis of positional information of the alignment marker.

When an alignment marker is provided on either one of the second bonding surface 40b of the lens unit 40 or the bonding surface of the prism unit 50, it is possible to identify the positions of the lens unit 40 and the prism unit 50 in a state where the optical axes of the lenses 42 (centers of output ports) provided in the lens unit 40 coincide with the optical axis of the prism unit 50 (a center of an input port), based on the positional information of the alignment marker.

### Laser module

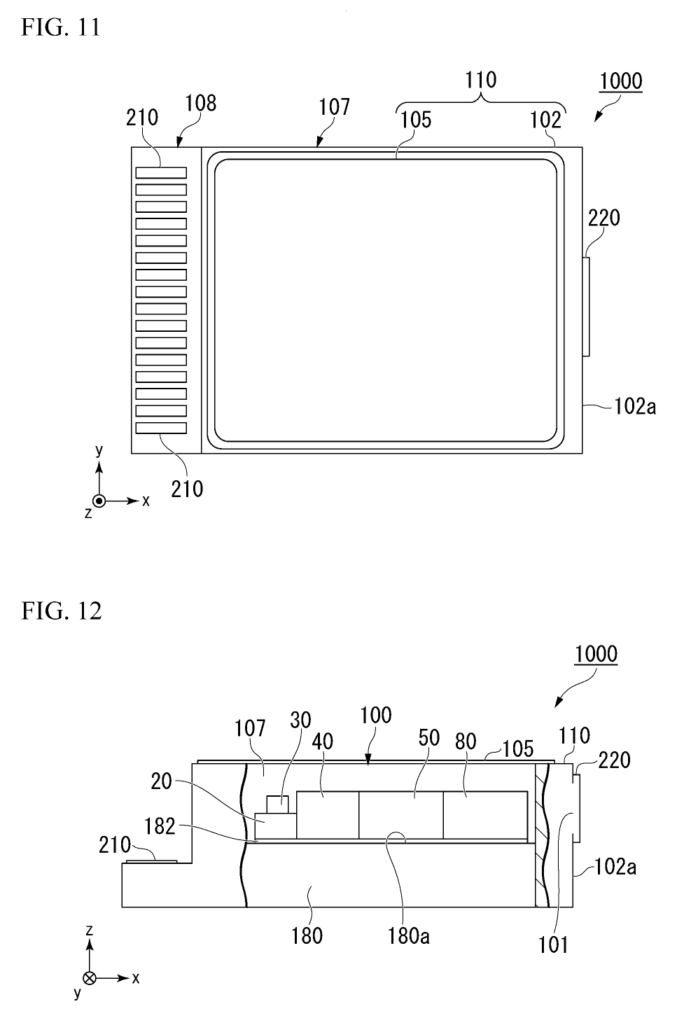

FIG. 11 is a schematic plan view of a laser module accommodating the optical coupling element assembly of the present disclosure. FIG. 12 is a view showing a cross section of the optical coupling element assembly arranged inside the laser module shown in FIG. 11, partially cut along an X-Z plane.

In a laser module 1000 shown in FIG. 11, the optical coupling element assembly 100 according to the foregoing embodiment is fixed to an upper surface 180a of a base 180 with an adhesion layer 182 therebetween and is accommodated inside a package 110.

In the optical coupling element assembly 100 accommodated inside the package 110 and fixed to the upper surface 180a of the base 180, the subcarrier 20 including the laser light source 30 mounted thereon, the lens unit 40, the prism unit 50, and the output optical system base mount 90 including the output optical unit 80 mounted thereon are bonded and integrated in a state of being optically and positionally aligned.

Therefore, assembly of the laser module is extremely easy.

Inside the package 110, known constituent elements other than the laser assembly according to the foregoing embodiment may be provided. For example, a light receiver (photodetector: PD) can be accommodated.

When a PD is provided, variations in optical output of the laser element can be checked by observing the current flowing through the PD. In addition, a drive current of the laser element can be controlled such that the output becomes constant by monitoring the current flowing through the PD.

The package 110 includes a main body 102 having a cavity structure, and a cover 105 covering the main body 102.

The main body 102 has a bottom portion on which members accommodated therein are mounted, and side wall portions 102a arranged so as to surround the members from lateral sides.

A light-transmitting window 101 allowing the laser light L output from the laser light source 30 to be optically transmitted therethrough is formed in the side wall portion 102a arranged in a direction in which laser light is output.

Among the side wall portions of an accommodation portion 107, the light- transmitting window (opening) 101 is formed in the side wall portion 102a in the vicinity of the output portion of the laser light L output from the laser module 1000. The opening 101 is formed substantially centered at a position intersecting the optical axis of laser light output at the side wall portion 102a. The opening 101 is covered by a glass plate 220 from outside the side wall portions 102a with no gap therebetween. That is, the accommodation portion 107 is hermetically sealed by the glass plate 220 in addition to the cover 105. Although the glass plate 220 is used for hermetic sealing, the material is not limited to a glass plate as long as laser light can be transmitted through. Anti-reflection films (not shown) may be provided on both plate surfaces of the glass plate 220.

An electrode portion 108 is arranged on the front side of the accommodation portion 107 in the x direction, that is, on a rearward side in the x direction. The upper surface of the electrode portion 108 is positioned below the upper surface of the accommodation portion 107. The bottom surface of the electrode portion 108 is positioned at substantially the same height as the bottom surface of the accommodation portion 107. A plurality of external electrode pads 210 are provided on the upper surface of the electrode portion 108 with an interval therebetween in the y direction.

In order to enhance thermal conductivity properties, a material obtained by mixing a filler into a resin is preferably used for the adhesion layer 182. Examples of resins constituting the adhesion layer 182 include epoxy resin. In addition, copper powder, aluminum powder, alumina powder, or the like can be used as the filler for improving the thermal conductivity properties of the resin.

In order to maintain a certain level of thermal conductivity properties, the thermal conductivity of the adhesion layer 182 is preferably 0.5 W/m·K or higher, the thermal conductivity is more preferably 1 W/m·K or higher, and the thermal conductivity is still more preferably 4 W/m·K or higher.

### Optical engine and XR glasses

In this specification, an optical engine is a device including a plurality of light sources, an optical system including a coupling portion coupling a plurality of light rays output from the plurality of light sources into a single light ray, an optical scanning mirror reflecting, while changing an angle thereof, light output from the optical system so as to display an image, and a control element controlling the optical scanning mirror.

The optical engine of the present disclosure includes a light source module according to the present disclosure, and an optical scanning mirror reflecting, while changing an angle thereof, light output from the light source module so as to display an image.

Hereinafter, an image display device including the optical engine of the present disclosure will be described as an example. XR glasses are an example of the image display device.

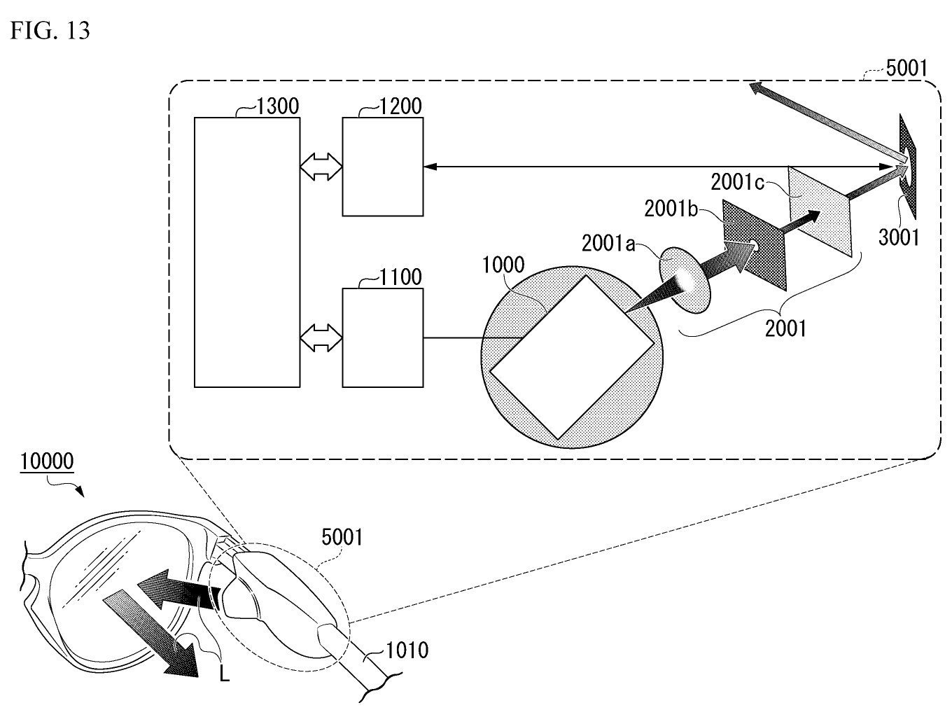

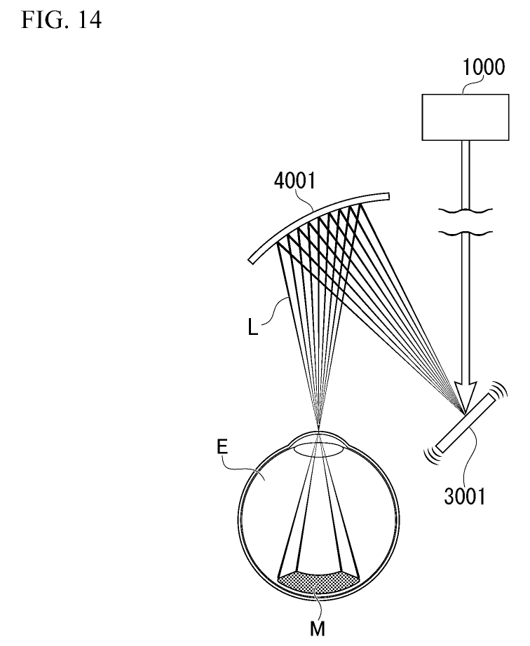

FIG. 13 is an explanatory conceptual view of an example of XR glasses of the present disclosure. FIG. 14 is a conceptual view showing a state where an image is directly projected onto a retina by laser light output from the light source module in the XR glasses shown in FIG. 13. The reference sign L indicates image display light.

XR glasses (eyeglasses) 10000 of the present disclosure are eyeglass-type terminals. “XR” is a collective term for virtual reality (VR), augmented reality (AR), and mixed reality (MR). The reference sign L shown in FIG. 14 indicates image display light.

In the XR glasses 10000 of the present disclosure shown in FIG. 13, the laser module 1000 according to the present disclosure is mounted on an optical engine 5001 installed in a frame 1010.

As shown in FIG. 13, the optical engine 5001 includes the laser module 1000, an optical scanning mirror 3001, an optical system 2001 connecting the laser module 1000 and the optical scanning mirror 3001, a laser driver 1100, an optical scanning mirror driver 1200, and a video controller 1300 controlling these drivers.

For example, a MEMS mirror can be used as the optical scanning mirror 3001. In order to project a two-dimensional image, it is preferable to use, as the optical scanning mirror 3001, a two-axis MEMS mirror vibrating so as to reflect laser light while changing an angle thereof in a horizontal direction (X direction) and a vertical direction (Y direction).

The optical system 2001 performs optical processing of laser light output from the laser module 1000. For example, the optical system 2001 including a collimator lens 2001a, a slit 2001b, and an ND filter 2001c can be used. The optical system 2001 shown in FIG. 13 is merely an example, and other configurations may be adopted.

In the XR glasses 10000 of the present disclosure shown in FIG. 13, as shown in FIG. 14, laser light R irradiated from the laser module 1000 attached to the frame 1010 is reflected by the optical scanning mirror 3001, is further reflected by a lens 4001 of the XR glasses 10000, and enters a human eyeball E as the image display light L, thereby allowing an image (video) to be directly projected onto a retina M.

Since the laser module 1000 of the present disclosure is mounted on the XR glasses 10000 of the present disclosure, electric field efficiency is reduced.

### INDUSTRIAL APPLICABILITY

An optical coupling element assembly of the present disclosure is suitably applicable to image display devices and XR glasses.

### EXPLANATION OF REFERENCES

20 Subcarrier

30 Laser light source

40 Lens unit

50 Prism unit

100, 100A, 100B Optical coupling element assembly

110 Package

1000 Laser module

5001 Optical engine

10000 XR glasses

What is claimed is:

1. An optical coupling element assembly comprising:
a plurality of laser light sources mounted on a subcarrier;
a lens unit in which a plurality of lenses are arranged side by side to convert a plurality of laser light rays output from the plurality of laser light sources into mutually parallel collimated rays; and
a prism unit formed by integrally combining a plurality of prisms to which a plurality of laser light rays that have passed through the lens unit are respectively input,
wherein a bonding surface of the subcarrier and a first bonding surface of the lens unit are bonded to each other,
a second bonding surface of the lens unit and a bonding surface of the prism unit are bonded to each other, and
each of the plurality of prisms includes an inclined surface reflecting and/or transmitting the laser light ray, the inclined surfaces are arranged parallel to each other such that the plurality of laser light rays reflected and/or transmitted are coupled into a single laser light ray, and the coupled laser light ray is output from an exit of the prism unit.

2. The optical coupling element assembly according to claim 1,
wherein the inclined surface of each of the prisms is coated with a thin film having wavelength selectivity, or has a microstructure formed thereon so as to have wavelength selectivity.

3. The optical coupling element assembly according to claim 1,
wherein either one of the first bonding surface of the lens unit or the bonding surface of the subcarrier has an alignment marker for positioning a counterpart to be bonded.

4. The optical coupling element assembly according to claim 1,
wherein either one of the second bonding surface of the lens unit or the bonding surface of the prism unit has an alignment marker for positioning a counterpart to be bonded.

5. The optical coupling element assembly according to claim 1,
wherein bonding between the bonding surface of the subcarrier and the first bonding surface of the lens unit is metal bonding or bonding using a UV-curable resin.

6. The optical coupling element assembly according to claim 1,
wherein bonding between the second bonding surface of the lens unit and the bonding surface of the prism unit is metal bonding or bonding using a UV-curable resin.

7. The optical coupling element assembly according to claim 1,
wherein each of the plurality of laser light sources is installed on the subcarrier at a position spaced apart from the first bonding surface of the lens unit by a distance of 0 μm to 50 μm.

8. The optical coupling element assembly according to claim 1,
wherein the subcarrier is made of aluminum nitride, aluminum oxide, or silicon.

9. The optical coupling element assembly according to claim 1,
wherein the lens unit includes a lens base having a plurality of recesses, and the lenses are respectively accommodated and fixed in the plurality of recesses.

10. The optical coupling element assembly according to claim 1,
wherein the bonding surface of the subcarrier and the first bonding surface of the lens unit are positioned and bonded such that optical axes of the respective laser light rays output from the laser light sources coincide with optical axes of the respective lenses provided in the lens unit.

11. The optical coupling element assembly according to claim 1, further comprising:
an output optical system member provided downstream of the prism unit,
wherein the output optical system member includes a pinhole member having a pinhole for removing noise from the coupled laser light ray, or the output optical system member includes a collimating lens for collimating the coupled laser light ray.

12. The optical coupling element assembly according to claim 1,
wherein the subcarrier is a common member on which all of the plurality of laser light sources are mounted.

13. The optical coupling element assembly according to claim 1,
wherein the plurality of laser light sources are all visible-light laser light sources outputting visible light rays.

14. The optical coupling element assembly according to claim 13,
wherein a plurality of the visible light rays are red light, green light, and blue light.

15. An optical engine comprising:
the optical coupling element assembly according to claim 14; and
an optical scanning mirror reflecting, while changing an angle thereof, light output from the optical coupling element assembly so as to display an image.

16. An image display device comprising:
the optical engine according to claim 15 mounted thereon.

17. XR glasses comprising:
the optical engine according to claim 15 mounted thereon.

18. A method for manufacturing the optical coupling element assembly according to claim 1, the method comprising:
a step of bonding the subcarrier and the plurality of laser light sources;
a step of bonding the subcarrier and the lens unit; and
a step of bonding the lens unit and the prism unit.

19. The method for manufacturing the optical coupling element assembly according to claim 18,
wherein either one of the first bonding surface of the lens unit or the bonding surface of the subcarrier has an alignment marker for positioning a counterpart to be bonded, and
the subcarrier and the lens unit are positioned and bonded on the basis of positional information of the alignment marker.

20. The method for manufacturing the optical coupling element assembly according to claim 18,
wherein either one of the second bonding surface of the lens unit or the bonding surface of the prism unit has an alignment marker for positioning a counterpart to be bonded, and
the lens unit and the prism unit are positioned and bonded on the basis of positional information of the alignment marker.
